(19) United States
(12) Patent Application Publication
(10) Pub. No.: US 2026/0290472 A1
(43) Pub. Date: Sep. 24, 2026

(54) DYNAMIC VOLTAGE SELECTION FOR MEMORY SYSTEMS

(71) Applicant: Micron Technology, Inc., Boise, ID (US)

(72) Inventors: Liang Yu, Boise, ID (US); Jonathan S. Parry, Boise, ID (US); Dustin L. Holloway, Meridian, ID (US)

(21) Appl. No.: 19/558,267

(22) Filed: Mar. 5, 2026

Related U.S. Application Data
(60) Provisional application No. 63/773,987, filed on Mar. 18, 2025.

(51) Int. Cl. G11C 16/30; G11C 5/14; G11C 16/34

(52) U.S. Cl. CPC G11C 16/30; G11C 5/148; G11C 16/3418

(57) ABSTRACT

Methods, systems, and devices for dynamic voltage selection for memory systems are described. A memory system may include an interface coupled with a corresponding interface of a host system, where the interface may include one or more pins operable to dynamically output a combination of signals indicating a set of voltage levels. During operation, the memory system may monitor a quantity of operating parameters, and may output the combination of signals via the one or more pins indicating a set of voltage levels selected in accordance with a change in one or more of the operating parameters. A host system may be operable to monitor one or more corresponding pins for an updated combination of signals, and may output an indication of the set of voltage levels to a power supply which may provide corresponding voltage levels for one or more power supply inputs to the memory system.

### CROSS REFERENCE

The present application for patent claims priority to U.S. Patent Application No. 63/773,987 by Yu et al., entitled “DYNAMIC VOLTAGE SELECTION FOR MEMORY SYSTEMS,” filed Mar. 18, 2025, which is assigned to the assignee hereof, and which is expressly incorporated by reference in its entirety herein.

### TECHNICAL FIELD

The following relates to one or more systems for memory, including dynamic voltage selection for memory systems.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not- or (NOR) and not- and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports dynamic voltage selection for memory systems in accordance with examples as disclosed herein.

FIG. 2 shows an example of a system that supports dynamic voltage selection for memory systems in accordance with examples as disclosed herein.

FIG. 3 shows an example of a flow diagram that supports dynamic voltage selection for memory systems in accordance with examples as disclosed herein.

FIG. 4 shows a block diagram of a memory system that supports dynamic voltage selection for memory systems in accordance with examples as disclosed herein.

FIG. 5 shows a flowchart illustrating a method or methods that support dynamic voltage selection for memory systems in accordance with examples as disclosed herein.

### DETAILED DESCRIPTION

In some examples, a memory system may be coupled with a host system (e.g., a system on a chip (SoC)) as well as a power supply. In some cases, the power supply may be an example of a power management integrated circuit (PMIC) that may be coupled with, or included in, the host system. The host system and the power supply may support various functions of the memory system, one of which may include supplying power to the memory system. For example, the memory system may include a first interface with one or more power supply inputs coupled with the power supply, including a first power supply input (e.g., Vcc) and a second power supply input (e.g., Vccq). In some cases, the first power supply input may have a first voltage level (e.g., 2.5 Volts (V)) and may supply power to one or more memory devices of the memory system, while the second power input may have a second voltage level (e.g., 1.2 V) and may supply power to a controller (e.g., an application specific integrated circuit (ASIC)) of the memory system as well as the one or more memory devices. Some memory systems may include a regulator, such as a low-dropout (LDO) regulator coupled with the second power supply input to power one or more components of the controller (e.g., logic circuitry, a core) at a third, lower voltage level (e.g., below 1.2 V). Using a lower voltage to power the one or more components of the controller may reduce power consumption and thermal load. For example, improvements in controller design and process nodes having smaller feature sizes may reduce operating voltage for the circuit components (e.g., transistors), which may reduce power consumption. Other systems, in place of the regulator, may include a third power supply input (e.g., Vccq2, VccqX), which may be coupled with the controller and may be configured to power the one or more components at the third voltage. In some examples, a memory system may statically configure one or more pins to output one or more settings for the first, second, and third voltage levels in a static configuration to enable custom configurations of voltage levels. In some cases, there may be opportunities for further power configuration of memory systems during operation by implementing dynamic voltage selection using the one or more pins.

As described herein, the memory system may be configured to support dynamic voltage selection for power supply inputs. For example, the memory system may include a second interface coupled with a corresponding interface of the host system, where the second interface may include one or more pins that may be operable to output a combination of signals (e.g., a dynamically configured combination) indicating a set of voltage levels (e.g., selected voltage level settings for a selected combination of signals), where the set may include settings for the first voltage level, the second voltage level, and the third voltage level (e.g., corresponding settings may correspond to the indicated set of voltage levels, including an updated voltage level applied to each of the power supply inputs). During operation, the memory system may monitor a quantity of operating parameters, and may output the combination of signals via the one or more pins indicating a set of voltage levels selected in accordance with a change in one or more of the operating parameters. The host system may be operable to monitor one or more corresponding pins for an updated combination of signals, and may output an indication of the set of voltage levels to the power supply (e.g., PMIC) via another interface of the host system. In some cases, the power supply may provide the corresponding voltage levels for each of the power supply inputs, for example, using dynamic voltage scaling (DVS). In some examples, the updated combination of signals may be in accordance with monitoring a temperature of the memory system, monitoring a current of the memory system, entering or exiting one or more sleep modes or low speed modes, among other operating parameters.

As opposed to other different methods involving static voltage configurations for a power supply, the techniques described herein may enable improved system flexibility. For example, dynamic voltage selection may enable the power supply to adjust one or more voltages during operation, which may enable the memory system, the host system, the power supply, or any combination, to reduce power consumption, for example, in cases in which a power used in one or more components may vary while operating. In such a case, lowering a voltage dynamically may enable further power savings as well as to reduce a thermal load of one or more components in an overall system. Additionally, or alternatively, using DVS may reduce a leakage current in one or more memory devices, further reducing thermal load and wear on one or more components of the system.

In addition to applicability in memory systems as described herein, techniques for dynamic voltage selection for memory systems may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by increasing efficiency and decreasing power consumption and related thermal load, as well as decreasing further thermal load due to leakage current in a system, which may extend the life and use of electronic devices, thereby reducing electronic waste, among other benefits. Using configurable pins may further reduce waste due to additional manufacturing.

Features of the disclosure are illustrated and described in the context of systems, devices, and circuits. Features of the disclosure are further illustrated and described in the context of systems, devices, circuits, flow diagrams, and flowcharts.

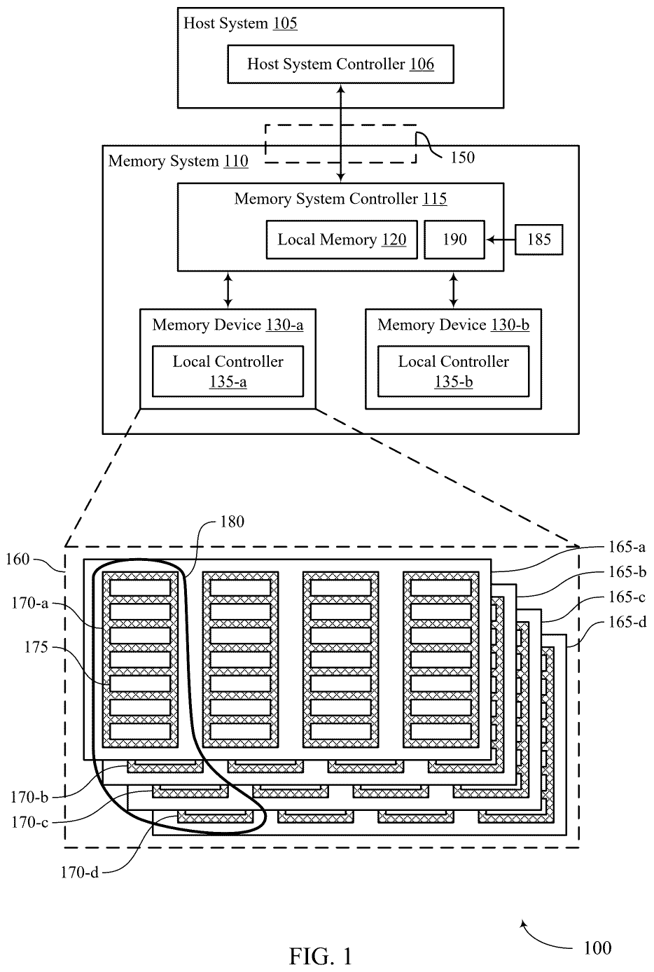

FIG. 1 shows an example of a system 100 that supports dynamic voltage selection for memory systems in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

As described herein, the memory system 110 may be configured to support dynamic voltage selection for power supply inputs. For example, the memory system 110 may include an interface 150 coupled with a corresponding interface of the host system 105, where the interface 150 may include one or more pins that may be operable to dynamically output a combination of signals (e.g., a dynamically updated combination) during operation indicating a set of voltage levels. During operation, the memory system 110 may monitor a quantity of operating parameters, and may output a combination of signals via the one or more pins indicating the set of voltage levels selected in accordance with a change in one or more operating parameters. For example, the memory system 110 may include one or more sensors 185 (e.g., temperature sensor(s), current sensor(s)) that may be used to monitor various parameters (e.g., temperature, leakage current, among other parameters). In some examples, the memory system 110 may include logic 190 (e.g., in the memory system controller 115) that may be used to compare the one or more operating parameters with one or more thresholds and truth tables for determining corresponding settings for the set of voltage levels. Additionally, or alternatively, the updated combination of signals may be in accordance with one or more sleep modes or low speed modes, among other operating parameters.

The host system 105 may be operable to monitor one or more corresponding pins for an updated combination of signals, and may output an indication of the set of voltage levels to a power supply (e.g., PMIC) via another interface of the host system 105. The power supply may provide the corresponding voltage levels for one or more power supply inputs, for example, using DVS. In some examples, the techniques described herein may enable improved system flexibility. For example, dynamic voltage adjustment may enable a PMIC to adjust one or more voltages during operation, which may enable components of the system 100 to save additional power. Additionally, or alternatively, DVS may reduce a leakage current in one or more memory devices, further reducing thermal load and ware on components of the system 100.

The system 100 may include any quantity of non-transitory computer readable media that support dynamic voltage selection for memory systems. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

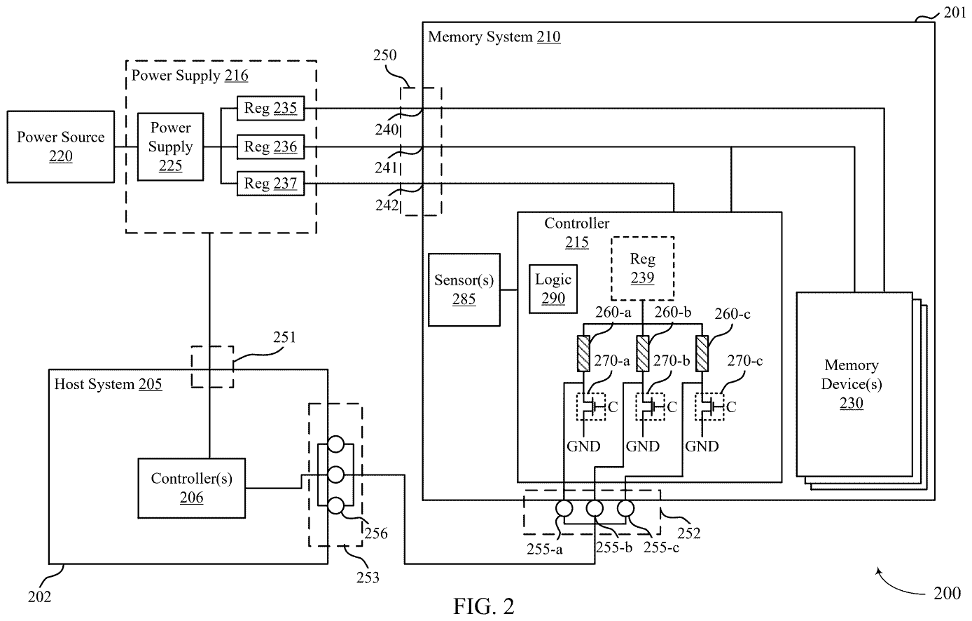

FIG. 2 shows an example of a system 200 that supports dynamic voltage selection for memory systems in accordance with examples as disclosed herein. In some examples, the system 200 may support aspects of the system 100. For example, the system 200 may include a host system 205, a memory system 210, one or more memory devices 230, a controller 215, and one or more controllers 206, which may be examples of a host system 105, a memory system 110, one or more memory devices 130, one or more memory system controllers 115 (or local controllers 135), and one or more host system controllers 106 as described with reference to FIG. 1, respectively. In some examples, the memory system 210 may support dynamic voltage selection for one or more power supply inputs as described herein.

For example, a power supply 216 may power one or more components of the memory system 210 (e.g., a memory module including an ASIC and NAND memory) via one or more power supply inputs. As shown in FIG. 2, the memory system 210 may include an interface 250 of a substrate 201 (e.g., a physical substrate on which one or more components of the memory system 210 are attached, mounted, or formed, a printed circuit board (PCB)) of the memory system 210, where the interface 250 may be coupled with the power supply 216 (e.g., a PMIC). The power supply 216 may be coupled with a power source 220 (e.g., a power source, a battery). The power supply 216 may also include a regulator 235 (e.g., an LDO regulator), a regulator 236, and a regulator 237. In some examples, the power supply 216 may further include an individual power supply 225 that may be coupled with the power source 220 and with one or more of the regulators 235, 236 and 237. Additionally, or alternatively, one or more of the regulators 235, 236, and 237 may be coupled directly with the power source 220, or multiple power supplies 225 may be included in the power supply 216 (e.g., individual power supplies for respective regulators). In some cases, the power supply 225 may be an example of a switched mode power supply (SMPSs). In some examples, a voltage level of the power source 220 may be greater than voltages used by the memory system 210 (e.g., the voltage level of the power source 220 may be a DC voltage in a range of 3V to 5V, or may be an AC voltage). The power supply 216 may be coupled with the host system 205 via one or more interfaces, such as via an interface 251 of the host system 205, or may be included in the host system 205, for example, attached to a same substrate 202 of the host system 105 to which the one or more controllers 206 may be attached.

In some examples, the interface 250 of the memory system 210 may include a first power supply input 240, a second power supply input 241, and a third power supply input 242, where each power supply input may be coupled with the power supply 216. For example, the regulator 235 may be coupled with the first power supply input 240 (e.g., a first power supply input coupled with a first voltage source, such as a first power rail), and may be configured to regulate a voltage supplied to the first power supply input 240 of the memory system 210 such that the voltage is equal to a first voltage level (e.g., 2.5 V). The regulator 236 may be coupled with the second power supply input 241 (e.g., a second power supply input coupled with a second voltage source, such as with a second power rail), and may be configured to regulate a voltage supplied to the second power supply input 241 such that the voltage is equal to a second voltage level (e.g., 1.2 V). The regulator 237 may be coupled with the third power supply input 242 (e.g., a third power supply input coupled with a third voltage source, such as with a third power rail), and may be configured to regulate a voltage supplied to the third power supply input 242 such that the voltage is equal to a third voltage level (e.g., at or between 0.6 V and 1.0 V).

In some examples, the first power supply input 240 may be coupled with the one or more memory devices 230 (e.g., one or more memory devices mounted to the substrate 201) and may be configured to power one or more first components (e.g., may power array circuitry, such as for programming/erasing or biasing components of one or more arrays) of the one or more memory devices 230 at the first voltage level. The second power supply input 241 may be coupled with the one or more memory devices 230, but may be configured to power one or more second components of the one or more memory devices 230 at the second voltage level (e.g., may power input/output for communication between the controller 215 and the one or more memory devices 230). Further, the power supply input 241 may in some cases power one or more components of the controller 215 at the second voltage level. The third power supply input 242 may be coupled with the controller 215 (e.g., a controller mounted to the substrate 201) and may be configured to power one or more components of the controller 215 at the third voltage level. For example, the third power supply input 242 may power a core of the controller 215 (e.g., provide Vccq2, provide Vccq_core to provide a lower voltage to a UFS ASIC core). Optionally, the third power supply input 242 may also power other low voltage domains of the controller 215 or the memory device 230, such as a physical layer, low density parity check (LDPC), ODT, etc.

In some examples, the controller 215 may include one or more regulators, such as a regulator 239 (e.g., an LDO regulator), which may be coupled with the third power supply input 242. The regulator 239 may lower an initial voltage of the third power supply input 242 (e.g., to lower Vccq2=1.0 V to a lower voltage). In some cases, the regulator 239 may be coupled with the core of the controller 215 and may be configured to regulate a voltage supplied to the core (e.g., lower 1.0 V to 0.75 V). In another example, if the core is powered by the power supply input 241 (e.g., Vccq), the power supply input 241 may be coupled with the regulator 239 to lower a voltage supplied to the core. In yet another example, the memory system 210 may include one or more power supplies or regulators coupled with one or more of the first power supply input 240 or the second power supply input 241, or the third power supply inputs 242.

In some examples, the memory system 210 may include an interface 252 (e.g., a second interface) including a quantity of pins (e.g., a set of one or more pins). For example, the interface 252 may include a quantity of pins 255 that may be configured to be coupled with a corresponding interface 253 of the host system 205 and with the controller 215, where the interface 253 may include one or more corresponding pins 256. The pins and interfaces may enable communication between the controller 215 and one or more components of the memory system 210 with the one or more controllers 206 and one or more components of the host system 205. For example, the interface 252 and the interface 253 and associated pins may exchange M-PHY signaling. In some cases, the quantity of pins 255 may include one or more solder balls (e.g., one or more balls reserved for use, or repurposed for indicating voltage levels). Further, the quantity of pins 255 may be referred to as power identifier/identification (PID) pins.

In some examples, the memory system 210 (e.g., via the controller 215) may be operable to monitor a set of multiple operating parameters and to output (e.g., during operation) a combination of signals in accordance with one or more of the operating parameters. For example, the memory system 210 may include one or more sensors 285, including one or more temperature sensors or current sensors coupled with the controller 215, where the controller 215 may be configured to monitor a temperature or leakage current associated with the memory system 210, with the controller 215, or a combination thereof, using the one or more sensors. In some examples, the one or more sensors 285 may be within the controller 215, attached or mounted to the substrate 201, or within one or more memory devices 230, or any combination thereof.

Additionally, or alternatively, the memory system 210 may include logic 290 (e.g., logic circuitry), for example, within the controller 215, or elsewhere in the memory system 210. In some cases, the logic 290 may include logic circuitry that may be configured to compare one or more operating parameters to one or more thresholds. For example, the logic 290 may compare monitored data received from the one or more sensors 285 (e.g., temperature data, leakage current data) to one or more thresholds. The logic 290 may also include logic circuitry for comparing one or more operating parameters or results from threshold comparisons to a truth table. The memory system 210, the controller 215, or the logic 290 may include local storage for storing one or more truth tables used in comparisons at the logic 290.

The memory system 210 may further include circuitry for outputting a combination of signals in accordance with one or more operating parameters. For example, the memory system 210 may include a set of multiple switches 270 of the controller 215 that may be coupled with the quantity of pins 255. In some cases, the controller 215 may include a switch 270-a, a switch 270-b, and a switch 270-c coupled with pins 255-a, 255-b, and 255-c, respectively. In some cases, each switch 270 may be an example of a transistor or other switching element. Additionally, or alternatively, the memory system 110 may include one or more resistors 260 of the controller 215 that may be coupled with one or more pins 255 of the quantity of pins 255, such as resistors 260-a, 260-b, and 260-c. In some cases, the one or more resistors 260 and/or the one or more switches 270 may be coupled with an internal pull-up (or pull-down) power supply (e.g., pull up/pull down or complementary metal-oxide semiconductor (CMOS) circuits to generate a PID [2:0] bias). For example, the one or more resistors 260 may be coupled with an internal power supply, such as the regulator 239, or another regulator, which may be supplied by one or more of the power supply inputs. For example, a regulator (the regulator 239, another regulator) may be an “always on” (Aon) LDO regulator (e.g., which receives power while the PMIC is outputting power), and may lower Vccq from 1.2 V to 0.8 V, where the 0.8 V may be supplied for a main pull-up or pull-down power supply. In some cases, the controller may be operable to configure each pin of the quantity of pins 255 to output a first signal (e.g., a logical value of ‘1’ or a logical value of ‘0’) or a second signal (e.g., the other of the logical value of ‘1 or the logical value of ‘0’) for the combination of signals in accordance with switching a respective switch 270. In some examples, outputting the combination of signals may be in accordance with the comparisons of the one or more operating parameters to the one or more thresholds by the logic 290 and the comparisons with the truth table. For example, outputting the one or more parameters may be in accordance with a temperature threshold being satisfied, a current threshold being satisfied, or in accordance with entering or exiting one or more modes (e.g., sleep modes, speed modes, power modes).

In some examples, the combination of signals may indicate a set of voltage levels of a set of multiple sets of voltage levels, where each of sets may include respective settings for the first voltage level, the second voltage level, and the third voltage level. For example, one or more exemplary signal combinations indicating respective sets of voltage levels for DVS may be illustrated in Table 1.

TABLE 1

| Vcc | Vccq | Vccq2 | | | |
|---|---|---|---|---|---|
| (V) | (V) | (V) | PWR_ID0 | PWR_ID1 | PWR_ID2 |
| 2.5 | 1.2 | 0.80 | 0 | 0 | 0 |
| 2.5 | 1.2 | 0.80 | 1 | 1 | 1 |
| 2.5 | 1.2 | 1.00 | 1 | 0 | 1 |
| 2.5 | 1.2 | 0.80 | 1 | 0 | 0 |
| 2.5 | 1.2 | 0.75 | 0 | 1 | 1 |
| 2.5 | 1.2 | 0.70 | 0 | 1 | 0 |
| 2.5 | 1.2 | 0.65 | 1 | 1 | 0 |
| 2.5 | 1.2 | 0.60 | 0 | 0 | 1 |

In the examples of Table 1, the host system 205 may utilize a combination of three signals (for three pins 255 and corresponding pins 256) to determine supported UFS voltages for each of the first power supply input 240, the second power supply input 241, and the third power supply input 242 (e.g., Vcc, Vccq, and a third voltage). The PIDs PWR_ID0, PWR_ID1, and PWR_ID2 may represent signals corresponding to the pins 255-a, 255-b, and 255-c, which may indicate different example voltages as illustrated in Table 1. For example, the pins 255 may indicate bit values of ‘1’, ‘1’, and ‘0’ for a bit signal vector [2:0], which may correspond to an updated voltage setting for the third power supply input 242 as 0.65 V. Additionally, or alternatively, other bit combinations according to Table 1 may be considered. Further, while Table 1 may illustrate indicating an updated setting for the third voltage level, other examples may involve indicating updated settings for the first and second voltage levels, and other combinations of signals and voltage levels for each of the power supply inputs may be considered. In some cases, the third voltage level may be less than the first voltage level and the second voltage level. Further, while Table 1 may illustrate three signals (e.g., for three bits), other quantity of bits may be considered (e.g., the pins 255 may output an ID with four or more bits if there is Vccq support for 1.0 bV or lower is present, or for other power supply input/power rail combinations and associated voltage combinations).

In some examples, the host system 205 (e.g., a mobile host system, an automobile host system) may sense (e.g., detect) an updated combination of signals provided by the quantity of pins 255, and may configure the power supply 216 (e.g., PMIC) to provide corresponding voltages according to the set of voltage levels via the interface 251. For example, the one or more controllers 206 of the host system 205 may monitor the interface 253 during operation to receive the updated combination of signals via the quantity of pins 256. In response to the monitoring, the one or more controllers 206 may receive the combination of signals indicating the set of voltage levels via the quantity of pins 256. For example, the quantity of pins 256 may include a corresponding pin 256 for each of the pins 255-a, 255-b, and 255-c each indicating a respective signal (e.g., each indicating a respective logic value ‘1’ or a logical value ‘0’). The updated combination of signals may indicate the set of voltage levels, where the one or more controllers 206 may be operable to output an indication of the set of voltage levels to the power supply 216 via the interface 251 in accordance with the updated combination of signals. In some cases, the one or more controllers 206 may determine the set of voltage levels (e.g., via logic of the one or more controller 206) in response to the combination of signals, or may forward the combination of signals to the power supply 216. In some examples, the set of voltage levels may include one or more voltage levels for DVS operations for the power supply 216 and for one or more of the power supply inputs.

By implementing the circuitry of the controller 215 (e.g., an ASIC implementing PID circuits) to notify the host system 205 (e.g., a mobile SoC) and/or subsequently notify the power supply 216 (e.g., a PMIC) to operate DVS may reduce UFS leakage power, further reducing a thermal load on the system 200. Additionally, or alternatively, a PID may in some cases involve additional logic to encode UFS internal events into corresponding PID bits (e.g., to encode thermal information, speed mode information, ASIC core current information, low power mode status). Using the PID bits, a UFS device, such as the memory system 210, may notify the host system 205 and/or power supply 216 of corresponding dynamic voltage changes in line with the determinations made by the logic 290 and the operational parameters, which may provide more power efficient power voltages selected during operation.

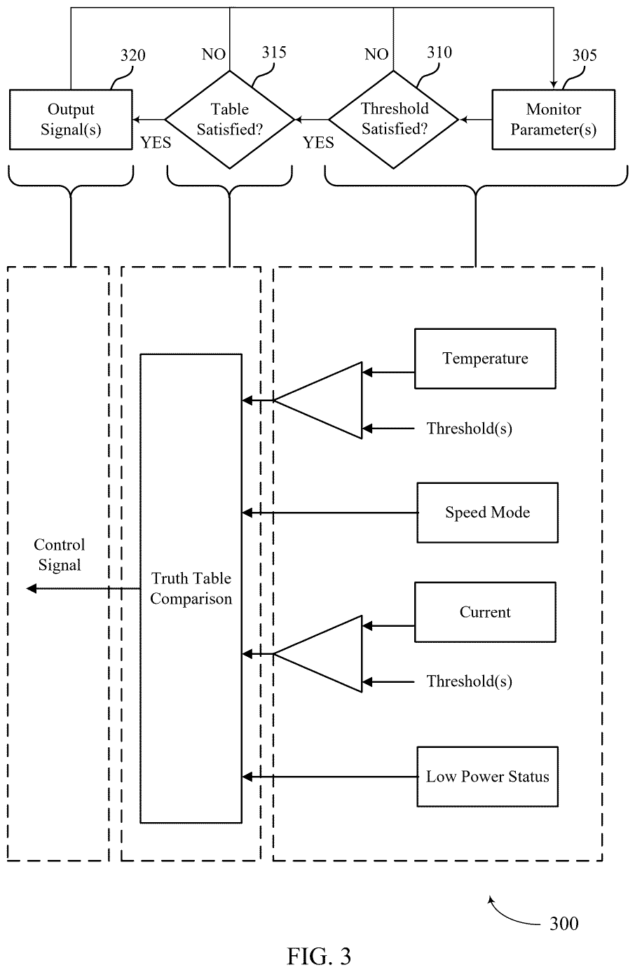

FIG. 3 shows an example of a process 300 that supports dynamic voltage selection for memory systems in accordance with examples as disclosed herein. One or more aspects of the process 300 of FIG. 3 may implement or may be implemented by one or more aspects of the system 100 and the system 200. For example, the process 300 may illustrate communications and operations performed at a memory system and using logic of the memory system, such as the memory system 210 and logic 290 described in FIG. 2 (or the memory system 110 described in FIG. 1). In some examples, the process 300 may support providing dynamic voltage selection in one or more memory systems.

In some examples, steps that the host system 205 performs in the process 300 can be implemented in instructions stored on memory of host system 205 and executed by the host system controller 206. Similarly, the steps that memory system 210 performs in the process 300 may be implemented in instructions or firmware stored on memory of the memory system 210 (e.g., in a memory device 230) and executed by the memory system controller 215 (and/or local controller(s), such as one or more local controllers 135).

At 305, one or more operating parameters may be monitored. For example, the memory system 210 may monitor (e.g., during a first duration for operation by the controller 215 on the substrate 201 of the memory system 210) a set of multiple operating parameters. In some cases, the memory system 210 may monitor a temperature associated with the memory system 210 (e.g., may include an ASIC thermal detector, such as a temperature monitor of the one or more sensors 185). Additionally, or alternatively, the memory system 210 may monitor a leakage current associated with the controller 215 (e.g., may include a core current detector, such as a current detector of the one or more sensors 185).

At 310, one or more operating parameters may be compared to one or more thresholds. For example, the logic 290 of the memory system 210 may compare the one or more operating parameters to one or more respective thresholds.

At 315, one or more operating parameters and one or more results of comparisons to thresholds may be compared to a truth table. For example, the memory system 210 may include a truth table (or other logic) and may compare, via the logic 290, a combination of operating parameters or results of the comparisons made at 310 to the truth table at 315.

At 320, one or more signals may be output by one or more components of the memory system 210. For example, the logic 290 of the memory system 210 may output a control signal (e.g., a control signal [2:0]) to the switches 270 of the configurable bit circuitry of the controller 215 in accordance with a change in one or more operating parameters. In response to the control signal and in accordance with the change in one or more operating parameters, the controller 215 may output, via the quantity of pins 255 of the interface 252 of the memory system 210, a combination of signals (e.g., a PID [2:0]).

In some examples, the memory system 210 may continuously, or periodically, monitor various operating parameters. Additionally, or alternatively, if one or more operating parameters fail to satisfy one or more thresholds at 310, or if criteria of the truth table is not met at 315, the memory system 210 may return to 305 to continue monitoring one or more of the same parameters (e.g., during a second duration for operation). Additionally, or alternatively, the memory system 210 may continue to monitor the same one or more operating parameters concurrent with performing logic operations at 310 and 315. The memory system 210 may also monitor one or more new or different operating parameters of the set of operating parameters subsequent to, concurrent with, or prior to the initial monitoring of the one or more operating parameters. In response to additional logic operations performed for the continued monitoring, the memory system 210 may output, via the one or more pins 255, a second combination of signals indicating a second set of voltage levels and corresponding settings for the voltage levels in accordance with a second change in the one or more operating parameters.

In some examples, the set of voltage levels may include one or more voltage levels for DVS operations for a power supply, such as the power supply 216, coupled with an interface, such as the interface 250, that may be coupled with the first power supply input 240, the second power supply input 241, and the third power supply input 242.

In some cases, the truth table may output a selected control signal for a selected combination of signals if a combination of various thresholds or modes are met as described in the following examples.

In some examples, outputting the combination of signals may be in accordance with determining that one or more temperatures of the memory system 210 satisfy one or more threshold temperatures. Further, in some examples, the memory system 210 may monitor, in response to determining that one or more temperatures satisfy one or more threshold temperatures, a leakage current associated with the controller 215 of the memory system 210, where outputting the combination of signals may be in accordance with determining that the leakage current satisfies a threshold leakage current.

For example, if a measured temperature of the controller 215 satisfies a maximum threshold (e.g., a ‘hot’ threshold), an ASIC core current detector may be triggered by the controller 215 due to a relatively large leakage current associated with relatively high temperatures. In some cases, other ASIC thermal throttling may be omitted. The controller 215 may dynamically change control signals (e.g., sent by the logic 290) and/or PIDs (e.g., sent via the pins 255) accordingly to request a change in settings for the power supply inputs. For example, a UFS ASIC may change a control signal [2:0] and a corresponding PID [2:0] from (0, 0, 1) to (1, 0, 1) to request that a Vccq2 voltage drops from 0.75 V to 0.7 V. Other voltage examples may also be considered as illustrated in Table 1, among other examples not shown. The host system 205 may sense a received PID at the pins 256 (e.g., an SoC may sense the PID) and may configure the power supply 216 accordingly. For example, an SoC may sense a corresponding PID signal, and may configure a PMIC with Vccq2 DVS from 0.75 V to 0.7 V during operation.

In some examples, the combination of signals may indicate an updated setting for the third voltage level, the second voltage level, or both. For example, with support for additional power supply input or power rail combinations for Table 1, Vccq could also be supported, for example, with DVS from 1.2 V to 1.1 V (e.g., if the memory system 210 includes Vcc and Vccq power rails but omits a Vccq2/Vccq_core power rail). In some cases, Vccq2 DVS may lower UFS ASIC current leakage to maintain a current budget (e.g., an ICCQ2 current budget) at a relatively higher temperature. Further, relatively higher temperatures may be associated with a lower speed of operation, and so reducing one or more voltages may reduce power consumption without negatively impacting performance (e.g., a power may be lowered without lowering an operating speed).

In some examples, the memory system 210 may enter a sleep mode or a low speed mode, where outputting the combination of signals at 320 may be in accordance with entering the sleep mode or the low speed mode. For example, if an SoC configures UFS devices to operate according to a high-speed (HS) gear-1 (G1) speed, or to enter a hibernate-8 (H8) or solid state unit (SSU) Sleep mode, the host system 205 may adjust one or more current levels (e.g., ICCactiveLevels) to be at a lower limit. Additionally, or alternatively, one or more devices may self-limit a current in HS G1 mode. In some examples, in response to entering the HS G1 speed or the H8 or SSU Sleep modes, the UFS ASIC may dynamically change a control signal or PID, for example, from (0, 0, 1) to (1, 0, 1) to request a Vccq2 voltage to drop from 0.75 V to 0.7 V (among other PID encoding examples). The SoC may sense the PID and may configure the PMIC with Vccq2 DVS from 0.75 V to 0.7 V. In some cases, with support for additional power rails combinations in Table 1, Vccq may also be supported, with DVS from 1.2 V to 1.1 V. In some examples, some power rails internal to the one or more memory devices 230 (e.g., internal to NAND) may be switched for additional power saving. In some cases, using DVS during HSG1 with PID dynamic change may enable power saving for one or more currents of the memory system 210 or host system 205 or power supply 216 (e.g., ICCQ power saving, ICC power saving, UFS total power saving, PMIC efficiency power saving).

In some examples, outputting the combination of signals may be in accordance with lowering a power associated with the memory system after entering the sleep mode, and the combination of signals may indicate an updated setting for the first voltage level, an updated setting for the second voltage level, and to power down the third voltage level. For example, if a UFS enters H8 or SSU Sleep with H8 status, and after the UFS has entered an LV2 status (e.g., an LV2 low power status for UFS ASIC), a UFS ASIC may dynamically alter a control signal or PID and may request Vccq2 (e.g., ASIC core voltage) to be switched off, as well as to lower Vcc from 2.5 V to 2.35 V and to lower Vccq from 1.2 V to 1.1 V. Further, one or more voltages may be increased in response to exiting the LV2 status and/or exiting the H8 or SSU Sleep modes. In some examples, additional PID bits may be included (e.g., more than three bits) to enable changes to Vcc and Vccq. The SoC may sense the PID and may configure the PMIC with the selected Vcc, Vccq, and Vccq2 voltages. Additionally, or alternatively, other modes and power statuses may be incorporated into the truth table and decisions made by the logic 290. In some cases, lowering one or more voltages for one or more power supply inputs during a sleep mode or a low speed mode may reduce power consumption in one or more components of the memory system 210.

In some examples of the techniques described herein, a definition for one or more bits may be redefined to change a granularity of voltage changes. For example, during a first duration, one or more PID bits may indicate granularities of 1.0 V, 0.8 V, 0.75 V, 0.7 V, etc. for different PID bit combinations for altering the third voltage level (e.g., Vccq). After the third voltage level is altered during operation, the memory system 210 or the host system 205 may alter an interpretation of, or indication associated with, PID bits for finer granularity control. For example, after a subsequent boot procedure following altering of the third voltage level, the pins 255 may indicate granularities of 0.75 V, 0.74 V, 0.73 V, etc. for one or more bit combinations of Table 1. An inverse procedure may also be supported to increase a granularity of voltage levels (e.g., after a boot-up procedure), and other example granularities may also be considered. In some examples, UFS ASIC current leakage may be reduced by utilizing a Vcc/Vccq DVS and a Vccq2 off condition as described herein.

In some examples, implementing dynamic voltage control may enable on-the-fly changes during operation of the memory system 210, improving a flexibility in power control of the system 200. Further, using the interface 252 (e.g., a PID interface with Logic) may replace one or more internal complex DVS operations in UFS, as well as enable DVS in systems or processes in which DVS may otherwise be unsupported. For example, to achieve UFS internal DVS, other NAND systems may perform internal Low Power Mode Standby (LPMS) (e.g., may change an output of an LDO regulator supplied by Vcc from 2.2 V to 1.8 V with a relatively complex entry/exit sequence), and a controller, such as an ASIC, may perform similar operations or add one or more sub-LDO regulators to provide a lower core voltage. As described herein, compared to such systems, the system 200 may instead reduce circuitry by omitting one or more additional LDO regulators, as well as reduce a complexity in operations. For example, the PID logic 290 may notify the host system 205 and the power supply 216 (e.g., mobile SoC/PMIC) to operate DVS dynamically during operation using one or more existing protocols and operations (e.g., PMIC DVS feature may be supported) as described herein in place of methods used by other UFS systems (e.g., other UFS systems may be unable to change one or more power supply inputs and associated voltage, such as a Vccq voltage, internally, or during operation).

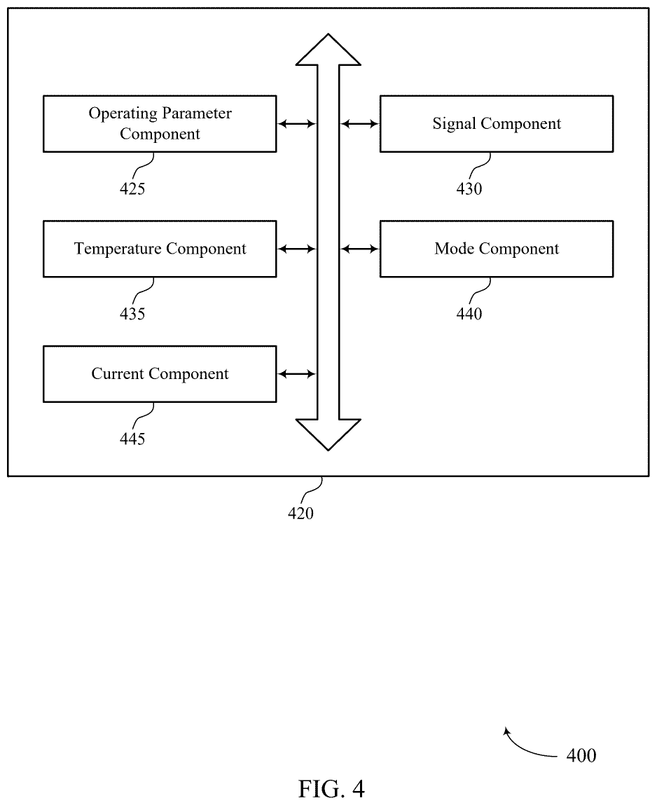

FIG. 4 shows a block diagram 400 of a memory system 420 that supports dynamic voltage selection for memory systems in accordance with examples as disclosed herein. The memory system 420 may be an example of aspects of a memory system as described with reference to FIGS. 1 through 3. The memory system 420, or various components thereof, may be an example of means for performing various aspects of dynamic voltage selection for memory systems as described herein. For example, the memory system 420 may include an operating parameter component 425, a signal component 430, a temperature component 435, a mode component 440, a current component 445, or any combination thereof. Each of these components, or components of subcomponents thereof (e.g., one or more processors, one or more memories), may communicate, directly or indirectly, with one another (e.g., via one or more buses).

The operating parameter component 425 may be configured as or otherwise support a means for monitoring, during a duration for operation and by a controller on a substrate of the memory system, a plurality of operating parameters. The signal component 430 may be configured as or otherwise support a means for outputting, via one or more pins of an interface of the memory system, a combination of signals in accordance with a change in one or more operating parameters of the plurality of operating parameters, the combination of signals indicating a set of voltage levels of a plurality of sets of voltage levels that is selected in accordance with the change in the one or more operating parameters, where a first power supply input and a second power supply input are coupled with one or more memory devices of the memory system and provide power for one or more first components and one or more second components of the one or more memory devices at a first voltage level and a second voltage level, respectively, and a third power supply input is coupled with the controller and provides power for one or more components of the controller at a third voltage level, where each of the plurality of sets of voltage levels includes settings for the first voltage level, the second voltage level, and the third voltage level.

In some examples, the operating parameter component 425 may be configured as or otherwise support a means for monitoring, during a second duration for operation and by the controller of the memory system, the plurality of operating parameters. In some examples, the signal component 430 may be configured as or otherwise support a means for outputting, via the one or more pins of the interface of the memory system, a second combination of signals in accordance with a second change in the one or more operating parameters, the second combination of signals indicating a second set of voltage levels of the plurality of sets of voltage levels that is selected in accordance with the second change in the one or more operating parameters.

In some examples, the temperature component 435 may be configured as or otherwise support a means for monitoring a temperature associated with the memory system, where outputting the combination of signals is in accordance with determining that the temperature of the memory system satisfies a threshold temperature.

In some examples, the current component 445 may be configured as or otherwise support a means for monitoring, in response to determining that the temperature of the memory system satisfies the threshold temperature, a leakage current associated with the controller of the memory system, where outputting the combination of signals is in accordance with determining that the leakage current satisfies a threshold leakage current.

In some examples, the mode component 440 may be configured as or otherwise support a means for entering a sleep mode or a low speed mode, where outputting the combination of signals is in accordance with entering the sleep mode or the low speed mode.

In some examples, outputting the combination of signals is in accordance with lowering a power associated with the memory system after entering the sleep mode, and the combination of signals indicates an updated setting for the first voltage level, an updated setting for the second voltage level, and to power down the third voltage level.

In some examples, an updated setting for the third voltage level, or an updated setting for the second voltage level, or both.

In some examples, the set of voltage levels includes one or more voltage levels for dynamic voltage scale operations for a power supply coupled with an interface that is coupled with the first power supply input, the second power supply input, and the third power supply input.

In some examples, the third voltage level is less than the first voltage level and the second voltage level.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

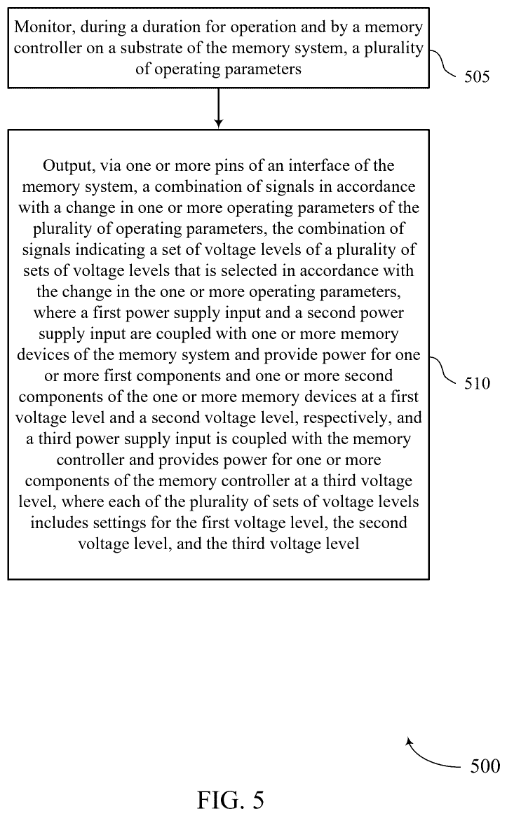

FIG. 5 shows a flowchart illustrating a method 500 that supports dynamic voltage selection for memory systems in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include monitoring, during a duration for operation and by a controller on a substrate of the memory system, a plurality of operating parameters. In some examples, aspects of the operations of 505 may be performed by an operating parameter component 425 as described with reference to FIG. 4.

At 510, the method may include outputting, via one or more pins of an interface of the memory system, a combination of signals in accordance with a change in one or more operating parameters of the plurality of operating parameters, the combination of signals indicating a set of voltage levels of a plurality of sets of voltage levels that is selected in accordance with the change in the one or more operating parameters, where a first power supply input and a second power supply input are coupled with one or more memory devices of the memory system and provide power for one or more first components and one or more second components of the one or more memory devices at a first voltage level and a second voltage level, respectively, and a third power supply input is coupled with the controller and provides power for one or more components of the controller at a third voltage level, where each of the plurality of sets of voltage levels includes settings for the first voltage level, the second voltage level, and the third voltage level. In some examples, aspects of the operations of 510 may be performed by a signal component 430 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for monitoring, during a duration for operation and by a controller on a substrate of the memory system, a plurality of operating parameters and outputting, via one or more pins of an interface of the memory system, a combination of signals in accordance with a change in one or more operating parameters of the plurality of operating parameters, the combination of signals indicating a set of voltage levels of a plurality of sets of voltage levels that is selected in accordance with the change in the one or more operating parameters, where a first power supply input and a second power supply input are coupled with one or more memory devices of the memory system and provide power for one or more first components and one or more second components of the one or more memory devices at a first voltage level and a second voltage level, respectively, and a third power supply input is coupled with the controller and provides power for one or more components of the controller at a third voltage level, where each of the plurality of sets of voltage levels includes settings for the first voltage level, the second voltage level, and the third voltage level.

Aspect 2: The method, apparatus, or non-transitory computer-readable medium of aspect 1, further including operations, features, circuitry, logic, means, or instructions, or any combination thereof for monitoring, during a second duration for operation and by the controller of the memory system, the plurality of operating parameters and outputting, via the one or more pins of the interface of the memory system, a second combination of signals in accordance with a second change in the one or more operating parameters, the second combination of signals indicating a second set of voltage levels of the plurality of sets of voltage levels that is selected in accordance with the second change in the one or more operating parameters.

Aspect 3: The method, apparatus, or non-transitory computer-readable medium of any of aspects 1 through 2, further including operations, features, circuitry, logic, means, or instructions, or any combination thereof for monitoring a temperature associated with the memory system, where outputting the combination of signals is in accordance with determining that the temperature of the memory system satisfies a threshold temperature.

Aspect 4: The method, apparatus, or non-transitory computer-readable medium of aspect 3, further including operations, features, circuitry, logic, means, or instructions, or any combination thereof for monitoring, in response to determining that the temperature of the memory system satisfies the threshold temperature, a leakage current associated with the controller of the memory system, where outputting the combination of signals is in accordance with determining that the leakage current satisfies a threshold leakage current.

Aspect 5: The method, apparatus, or non-transitory computer-readable medium of any of aspects 1 through 4, further including operations, features, circuitry, logic, means, or instructions, or any combination thereof for entering a sleep mode or a low speed mode, where outputting the combination of signals is in accordance with entering the sleep mode or the low speed mode.

Aspect 6: The method, apparatus, or non-transitory computer-readable medium of aspect 5, where outputting the combination of signals is in accordance with lowering a power associated with the memory system after entering the sleep mode, and the combination of signals indicates an updated setting for the first voltage level, an updated setting for the second voltage level, and to power down the third voltage level.

Aspect 7: The method, apparatus, or non-transitory computer-readable medium of any of aspects 1 through 6, where an updated setting for the third voltage level, or an updated setting for the second voltage level, or both.

Aspect 8: The method, apparatus, or non-transitory computer-readable medium of any of aspects 1 through 7, where the set of voltage levels includes one or more voltage levels for dynamic voltage scale operations for a power supply coupled with an interface that is coupled with the first power supply input, the second power supply input, and the third power supply input.

Aspect 9: The method, apparatus, or non-transitory computer-readable medium of any of aspects 1 through 8, where the third voltage level is less than the first voltage level and the second voltage level.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: A memory system, including: a controller mounted to a substrate; one or more memory devices mounted to the substrate and coupled with the controller; a first interface of the substrate including a first power supply input, a second power supply input, and a third power supply input, where the first power supply input and the second power supply input are coupled with the one or more memory devices and provide power for one or more first components and one or more second components of the one or more memory devices at a first voltage level and a second voltage level, respectively, and where the third power supply input is coupled with the controller and provides power for one or more components of the controller at a third voltage level; and a second interface of the substrate including a plurality of pins configured to be coupled with a corresponding interface of a host system and the controller, the controller operable to monitor a plurality of operating parameters and to output a combination of signals in accordance with one or more operating parameters of the plurality of operating parameters, the combination of signals indicating a set of voltage levels of a plurality of sets of voltage levels, where each of the plurality of sets of voltage levels includes settings for the first voltage level, the second voltage level, and the third voltage level.

Aspect 11: The memory system of aspect 10, further including: logic circuitry of the controller, where: the logic circuitry is configured to compare the one or more operating parameters to one or more thresholds, and the combination of signals is in accordance with the comparison and a truth table.

Aspect 12: The memory system of any of aspects 10 through 11, further including: one or more temperature sensors coupled with the controller, where the controller is configured to monitor a temperature associated with the memory system using the one or more temperature sensors, where outputting the combination of signals is in accordance with determining that the temperature of the memory system satisfies a threshold temperature.

Aspect 13: The memory system of aspect 12, further including: one or more current sensors coupled with the controller, where the controller is configured to monitor, in response to determining that the temperature of the memory system satisfies the threshold temperature, a leakage current associated with the controller of the memory system, where outputting the combination of signals is in accordance with determining that the leakage current satisfies a threshold leakage current.

Aspect 14: The memory system of any of aspects 10 through 13, where outputting the combination of signals is in accordance with entering a sleep mode or entering a low speed mode.

Aspect 15: The memory system of aspect 14, where: outputting the combination of signals is in accordance with lowering a power associated with the memory system after entering the sleep mode, and the combination of signals indicates an updated setting for the first voltage level, an updated setting for the second voltage level, and to power down the third voltage level.

Aspect 16: The memory system of any of aspects 10 through 15, further including: a plurality of switches of the controller that are coupled with the plurality of pins, where the controller is operable to configure each pin of the plurality of pins to output a first signal or a second signal for the combination of signals in accordance with switching a respective switch of the plurality of switches; and one or more resistors of the controller and coupled with one or more pins of the plurality of pins, where the one or more resistors are coupled with a voltage regulator of the controller.

Aspect 17: The memory system of any of aspects 10 through 16, where the combination of signals indicates: an updated setting for the third voltage level, or an updated setting for the second voltage level, or both.

Aspect 18: The memory system of any of aspects 10 through 17, where the set of voltage levels includes one or more voltage levels for dynamic voltage scale operations for the first power supply input, the second power supply input, and the third power supply input.

Aspect 19: The memory system of any of aspects 10 through 18, where the third voltage level is less than the first voltage level and the second voltage level.

An apparatus is described. The following provides an overview of aspects of the apparatus as described herein:

Aspect 20: A host system, including: one or more controllers; a first interface coupled with a power supply and the one or more controllers; and a second interface including a plurality of pins coupled with a corresponding interface of a memory system and the one or more controllers, the one or more controllers configured to monitor the second interface during operation to receive an updated combination of signals via the plurality of pins, where the one or more controllers are configured to indicate a set of voltage levels of a plurality of sets of voltage levels to the power supply via the first interface in accordance with the updated combination of signals, where each of the plurality of sets of voltage levels includes settings for a first voltage level, a second voltage level, and a third voltage level.

Aspect 21: The host system of aspect 20, where the one or more controllers are operable to determine the set of voltage levels of the plurality of sets of voltage levels in response to the updated combination of signals.

Aspect 22: The host system of any of aspects 20 through 21, where the updated combination of signals indicates one or more updated settings for one or more voltage levels of the set of voltage levels.

Aspect 23: The host system of any of aspects 20 through 22, where the set of voltage levels includes one or more voltage levels for dynamic voltage scale operations for the power supply.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
a controller mounted to a substrate;
one or more memory devices mounted to the substrate and coupled with the controller;
a first interface of the substrate comprising a first power supply input, a second power supply input, and a third power supply input, wherein the first power supply input and the second power supply input are coupled with the one or more memory devices and provide power for one or more first components and one or more second components of the one or more memory devices at a first voltage level and a second voltage level, respectively, and wherein the third power supply input is coupled with the controller and provides power for one or more components of the controller at a third voltage level; and
a second interface of the substrate comprising a plurality of pins configured to be coupled with a corresponding interface of a host system and the controller, the controller operable to monitor a plurality of operating parameters and to output a combination of signals in accordance with one or more operating parameters of the plurality of operating parameters, the combination of signals indicating a set of voltage levels of a plurality of sets of voltage levels, wherein each of the plurality of sets of voltage levels comprises settings for the first voltage level, the second voltage level, and the third voltage level.

2. The memory system of claim 1, further comprising:
logic circuitry of the controller, wherein:
the logic circuitry is configured to compare the one or more operating parameters to one or more thresholds, and
the combination of signals is in accordance with the comparison and a truth table.

3. The memory system of claim 1, further comprising:
one or more temperature sensors coupled with the controller, wherein the controller is configured to monitor a temperature associated with the memory system using the one or more temperature sensors, wherein outputting the combination of signals is in accordance with determining that the temperature of the memory system satisfies a threshold temperature.

4. The memory system of claim 3, further comprising:
one or more current sensors coupled with the controller, wherein the controller is configured to monitor, in response to determining that the temperature of the memory system satisfies the threshold temperature, a leakage current associated with the controller of the memory system, wherein outputting the combination of signals is in accordance with determining that the leakage current satisfies a threshold leakage current.

5. The memory system of claim 1, wherein outputting the combination of signals is in accordance with entering a sleep mode or entering a low speed mode.

6. The memory system of claim 5, wherein:
outputting the combination of signals is in accordance with lowering a power associated with the memory system after entering the sleep mode, and
the combination of signals indicates an updated setting for the first voltage level, an updated setting for the second voltage level, and to power down the third voltage level.

7. The memory system of claim 1, further comprising:
a plurality of switches of the controller that are coupled with the plurality of pins, wherein the controller is operable to configure each pin of the plurality of pins to output a first signal or a second signal for the combination of signals in accordance with switching a respective switch of the plurality of switches; and
one or more resistors of the controller and coupled with one or more pins of the plurality of pins, wherein the one or more resistors are coupled with a voltage regulator of the controller.

8. The memory system of claim 1, wherein the combination of signals indicates:
an updated setting for the third voltage level, or
an updated setting for the second voltage level, or both.

9. The memory system of claim 1, wherein the set of voltage levels comprises one or more voltage levels for dynamic voltage scale operations for the first power supply input, the second power supply input, and the third power supply input.

10. The memory system of claim 1, wherein the third voltage level is less than the first voltage level and the second voltage level.

11. A host system, comprising:
one or more controllers;
a first interface coupled with a power supply and the one or more controllers; and
a second interface comprising a plurality of pins coupled with a corresponding interface of a memory system and the one or more controllers, the one or more controllers configured to monitor the second interface during operation to receive an updated combination of signals via the plurality of pins, wherein the one or more controllers are configured to indicate a set of voltage levels of a plurality of sets of voltage levels to the power supply via the first interface in accordance with the updated combination of signals, wherein each of the plurality of sets of voltage levels comprises settings for a first voltage level, a second voltage level, and a third voltage level.

12. The host system of claim 11, wherein the one or more controllers are operable to determine the set of voltage levels of the plurality of sets of voltage levels in response to the updated combination of signals.

13. The host system of claim 11, wherein the updated combination of signals indicates one or more updated settings for one or more voltage levels of the set of voltage levels.

14. The host system of claim 11, wherein the set of voltage levels comprises one or more voltage levels for dynamic voltage scale operations for the power supply.

15. A method by a memory system, comprising:
monitoring, during a duration for operation and by a controller on a substrate of the memory system, a plurality of operating parameters; and
outputting, via one or more pins of an interface of the memory system, a combination of signals in accordance with a change in one or more operating parameters of the plurality of operating parameters, the combination of signals indicating a set of voltage levels of a plurality of sets of voltage levels that is selected in accordance with the change in the one or more operating parameters, wherein a first power supply input and a second power supply input are coupled with one or more memory devices of the memory system and provide power for one or more first components and one or more second components of the one or more memory devices at a first voltage level and a second voltage level, respectively, and a third power supply input is coupled with the controller and provides power for one or more components of the controller at a third voltage level, wherein each of the plurality of sets of voltage levels comprises settings for the first voltage level, the second voltage level, and the third voltage level.

16. The method of claim 15, further comprising:
monitoring, during a second duration for operation and by the controller of the memory system, the plurality of operating parameters; and
outputting, via the one or more pins of the interface of the memory system, a second combination of signals in accordance with a second change in the one or more operating parameters, the second combination of signals indicating a second set of voltage levels of the plurality of sets of voltage levels that is selected in accordance with the second change in the one or more operating parameters.

17. The method of claim 15, further comprising:
monitoring a temperature associated with the memory system, wherein outputting the combination of signals is in accordance with determining that the temperature of the memory system satisfies a threshold temperature.

18. The method of claim 17, further comprising:
monitoring, in response to determining that the temperature of the memory system satisfies the threshold temperature, a leakage current associated with the controller of the memory system, wherein outputting the combination of signals is in accordance with determining that the leakage current satisfies a threshold leakage current.

19. The method of claim 15, further comprising:
entering a sleep mode or a low speed mode, wherein outputting the combination of signals is in accordance with entering the sleep mode or the low speed mode.

20. The method of claim 19, wherein outputting the combination of signals is in accordance with lowering a power associated with the memory system after entering the sleep mode, and the combination of signals indicates an updated setting for the first voltage level, an updated setting for the second voltage level, and to power down the third voltage level.

21. The memory system of claim 15, wherein the combination of signals indicates an updated setting for the third voltage level, or an updated setting for the second voltage level, or both.

22. The memory system of claim 15, wherein the set of voltage levels comprises one or more voltage levels for dynamic voltage scale operations for a power supply coupled with an interface that is coupled with the first power supply input, the second power supply input, and the third power supply input.

23. The memory system of claim 15, wherein the third voltage level is less than the first voltage level and the second voltage level.
